(19) United States
(12) Patent Application Publication
(10) Pub. No.: US 2012/0138126 A1
(43) Pub. Date: Jun. 7, 2012

(54) SOLAR CELL

(75) Inventor: Shigeo Yata, Kobe-shi (JP)

(73) Assignee: Sanyo Electric Co., Ltd., Moriguchi-shi, Osaka (JP)

(21) Appl. No.: 12/598,226

(22) PCT Filed: Mar. 18, 2009
(86) PCT No.: PCT/JP2009/055310

§ 371 Date: Jan. 15, 2010

(30) Foreign Application Priority Data
Mar. 21, 2008 (JP) 2008-074495

(51) Int. Cl. H01L 31/042; H01L 31/0687; H01L 31/0232

(52) U.S. Cl. 136/249; 136/259; 136/255

(57) ABSTRACT

A solar cell 10 comprising a light-receiving-surface electrode layer, a backside electrode layer 4 and a stacked body 3 provided between the light-receiving-surface electrode layer 2 and the backside electrode layer 4. The stacked body 3 includes a first photoelectric converter 31 and a reflective layer 32 reflecting a part of light, which has transmitted through the first photoelectric converter 31, toward the first photoelectric converter 31. The reflective layer 32 includes a low-refractive-index layer 32b containing a refractive index-modifier and a contact layer 32 interposed between the low-refractive-index layer 32b and the first photoelectric converter 31. A refractive index of a material constituting the refractive index-modifier is lower than a refractive index of a material constituting the contact layer 32a. A refractive index of the low-refractive-index layer 32b is lower than a refractive index of the contact layer 32a.

### TECHNICAL FIELD

The present invention relates to a solar cell including a reflective layer that reflects a part of incident light.

### BACKGROUND ART

A solar cell is expected to be a new energy source because the solar cell can directly convert sun light, which is a clean and unlimited energy source, into electricity.

Generally, a solar cell includes a photoelectric converter between a transparent electrode layer provided on a light-incident side and a backside electrode layer provided on the opposite side from the light-incident side. The photoelectric converter generates photo-generated carriers by absorbing light that enters the solar cell.

Conventionally, a method has been known in which a reflective layer for reflecting a part of incident light is provided between a photoelectric converter and a backside electrode layer. According to this method, the reflective layer reflects a part of light, which has transmitted through the photoelectric converter, toward the photoelectric converter. Thus, the amount of light absorbed in the photoelectric converter can be increased. As a result, the photo-generated carriers generated in the photoelectric converter are increased, thereby enabling the improvement in the photoelectric conversion efficiency of the solar cell.

Generally, zinc oxide (ZnO), which is a transparent conductive material, is used for such a reflective layer (see Michio Kondo et al., “Four terminal cell analysis of amorphous/microcrystalline Si tandem cell”).

Meanwhile, a further improvement in the photoelectric conversion efficiency of a solar cell has been demanded recently.

In this respect, in order to further improve the photoelectric conversion efficiency, it is effective to increase the photo-generated carriers generated in the photoelectric converter by increasing the light reflectivity of the reflective layer.

Therefore, the present invention has been made in view of the above-described circumstances, and an object of the present invention is to provide a solar cell achieving the improvement of its photoelectric conversion efficiency.

### DISCLOSURE OF THE INVENTION

A first aspect of the present invention is summarized as a solar cell 10 comprising a light-receiving-surface electrode layer 2 having conductivity and transparency, a backside electrode layer 4 having conductivity, and a stacked body 5 provided between the light-receiving-surface electrode layer 2 and the backside electrode layer 4, wherein the stacked body 5 includes a first photoelectric converter 51 generating photo-generated carriers from incident light, and a reflective layer 52 reflecting a part of light, which has transmitted through the first photoelectric converter 51, toward the first photoelectric converter 51, the reflective layer 52 includes a low-refractive-index layer 32b containing a refractive index-modifier, and a contact layer 32a interposed between the low-refractive-index layer 32b and the first photoelectric converter 51, a refractive index of a material constituting the refractive index-modifier is lower than a refractive index of a material constituting the contact layer 32a, and a refractive index of the low-refractive-index layer 32b is lower than a refractive index of the contact layer 32a.

In the solar cell 10 according to the first aspect of the present invention, the reflective layer 52 includes the low-refractive-index layer 32b containing the refractive index-modifier. Accordingly, it is possible to make the reflectivity of the reflective layer 52 higher than that of a conventional reflective layer mainly formed of ZnO or the like. Moreover, the contact layer 32a is interposed between the low-refractive-index layer 32b and the first photoelectric converter 51. Accordingly, it is possible to suppress an increase in the series resistance (series resistance) value of the solar cell 10 as a whole, the increase being attributed to the direct contact between the low-refractive-index layer 32b and first photoelectric converter 51. Thus, the solar cell 10 achieves the improvement in its photoelectric conversion efficiency.

One aspect of the present invention is in accordance with the above-described aspect of the present invention, and is summarized in that the stacked body 5 has a structure in which the first photoelectric converter 51, the reflective layer 52, and a second photoelectric converter 53 for generating photo-generated carriers from incident light are stacked in this order when viewed from a light-receiving-surface electrode layer 2 side, the reflective layer 52 further includes a different contact layer 32c interposed between the low-refractive-index layer 32b and the second photoelectric converter 53, the refractive index of the material constituting the refractive index-modifier is lower than a refractive index of a material constituting the different contact layer 32c, and the refractive index of the low-refractive-index layer 32b is lower than a refractive index of the different contact layer 32c.

One aspect of the present invention is in accordance with the above-described aspect of the present invention, and is summarized in that the contact layer 32a is constituted of a material having a contact resistance value with respect to the first photoelectric converter 51 being smaller than a contact resistance value between the low-refractive-index layer 32b and the first photoelectric converter 51.

One aspect of the present invention is in accordance with the above-described aspect of the present invention, and is summarized in that the different contact layer 32c is constituted of a material having a smaller contact resistance value with respect to the second photoelectric converter 53 than a contact resistance value between the low-refractive-index layer 32b and the second photoelectric converter 53.

One aspect of the present invention is in accordance with the above-described aspect of the present invention, and is summarized in that at least one of the contact layer 32a and the different contact layer 32c contains any one of zinc oxide and indium oxide.

One aspect of the present invention is summarized as a solar cell 10 comprising a first solar cell element 10a and a second solar cell element 10a on a substrate 1 having an insulating property and transparency, wherein each of the first solar cell element 10a and the second solar cell element 10a includes a light-receiving-surface electrode layer 2 having conductivity and transparency, a backside electrode layer 4 having conductivity and a stacked body 5 provided between the light-receiving-surface electrode layer 2 and the backside electrode layer 4, the stacked body 5 has a first photoelectric converter 51 generating photo-generated carriers from incident light, a reflective layer 52 reflecting a part of light, which has transmitted through the first photoelectric converter 51, toward the first photoelectric converter 51, and a second photoelectric converter 53 generating photo-generated carriers from incident light, the backside electrode layer 4 of the first solar cell element 10a has an extended portion 4a extending toward the light-receiving-surface electrode layer 2 of the second solar cell element 10a, the extended portion 4a is in contact with the reflective layer 52 exposed from a side surface of the stacked body 5 included in the first solar cell element 10a, the reflective layer 52 has a low-refractive-index layer 32b containing a refractive index-modifier; a contact layer 32a interposed between the low-refractive-index layer 32b and the first photoelectric converter 51; and a different contact layer 32c interposed between the low-refractive-index layer 32b and the second photoelectric converter 53, a refractive index of a material constituting the refractive index-modifier is lower than a refractive index of a material constituting the contact layer 32a and a refractive index of a material constituting the different contact layer 32c, and a refractive index of the low-refractive-index layer 32b is lower than a refractive index of the contact layer 32a and a refractive index of the different contact layer 32c.

### BRIEF DESCRIPTION OF THE DRAWINGS

FIG. 1 is a cross-sectional view of a solar cell 10 according to a first embodiment of the present invention.

FIG. 2 is a cross-sectional view of a solar cell 10 according to a second embodiment of the present invention.

FIG. 3 is a cross-sectional view of a solar cell 10 according to a third embodiment of the present invention.

FIG. 4 is a cross-sectional view of a solar cell 10 according to a fourth embodiment of the present invention.

FIG. 5 is a cross-sectional view of a solar cell 20 according to Comparative Example 1 and Comparative Example 2 of the present invention.

FIG. 6 is a cross-sectional view of a solar cell 30 according to Comparative Example 3 of the present invention.

### BEST MODES FOR CARRYING OUT THE INVENTION

Next, embodiments of the present invention will be described by use of the drawings. In the following description on the drawings, identical or similar parts are denoted by identical or similar reference symbols. It should be noted, however, that the drawings are schematic, and that the dimensional proportions and the like are different from their actual values. Accordingly, specific dimensions and the like should be determined on the basis of the description given below. Moreover, it is needless to say that dimensional relationships and dimensional proportions may be different from one drawing to another in some parts.

### First Embodiment

<Structure of Solar Cell>

Hereinbelow, a structure of a solar cell according to a first embodiment of the present invention will be described with reference to FIG. 1. FIG. 1 is a cross-sectional view of a solar cell 10 according to the first embodiment of the present invention.

As shown in FIG. 1, the solar cell 10 includes a substrate 1, a light-receiving-surface electrode layer 2, a stacked body 5, and a backside electrode layer 4.

The substrate 1 has transparency and is formed of a transparent material such as glass or plastic.

The light-receiving-surface electrode layer 2 is stacked on the substrate 1, and has conductivity and transparency. A metal oxide such as tin oxide (SnO₂), zinc oxide (ZnO), indium oxide (In₂O₂), or titanium oxide (TiO₂) can be used for the light-receiving-surface electrode layer 2. Incidentally, these metal oxides may be doped with fluorine (F), tin (Sn), aluminium (Al), iron (Fe), gallium (Ga), niobium (Nb), or the like.

The stacked body 5 is provided between the light-receiving-surface electrode layer 2 and the backside electrode layer 4. The stacked body 5 includes a first photoelectric converter 51 and a reflective layer 52. The first photoelectric converter 51 and the reflective layer 52 are stacked in this order when viewed from the light-receiving-surface electrode layer 2 side.

The first photoelectric converter 51 generates photo-generated carriers from light incident from a light-receiving-surface electrode layer 2 side thereof. Moreover, the first photoelectric converter 51 generates photo-generated carriers from light reflected by the reflective layer 52. The first photoelectric converter 51 has a pin junction (unillustrated) in which a p type amorphous silicon semiconductor, an i type amorphous silicon semiconductor, and an n type amorphous silicon semiconductor are stacked in this order when viewed from the substrate 1 side.

The reflective layer 52 reflects a part of light, which has transmitted through the first photoelectric converter 51, toward the first photoelectric converter 51. The reflective layer 52 includes a first layer 52a and a second layer 52b.

The first layer 52a and the second layer 52b are stacked in this order when viewed from the first photoelectric converter 51 side. Accordingly, the first layer 52a is in contact with the first photoelectric converter 51, whereas the second layer 52b is not in contact with the first photoelectric converter 51.

The second layer 52b contains: a binder constituted of a resin or the like; a transparent conductive material; and a refractive index-modifier. Silica or the like can be used as the binder. Moreover, ZnO, ITO, or the like can be used as the transparent conductive material. Furthermore, a material having a lower refractive index than the first layer 52a is used as the refractive index-modifier. For example, bubbles or fine particles constituted of SiO₂, Al₂O₃, MgO, CaF₂, NaF, CaO, LiF, MgF₂, SrO, B₂O₃, or the like can be used as the refractive index-modifier. Thus, a layer containing, for example, ITO particles and bubbles in a silica based binder can be used as the second layer 52b. Since the second layer 32b contains the refractive index-modifier as described above, the refractive index of the second layer 52b as a whole is lower than the refractive index of the first layer 52a.

As a material used as the first layer 52a, a material is used which has a smaller contact resistance value with respect to the first photoelectric converter 51 than the contact resistance value between the material constituting the second layer 52b and the first photoelectric converter 51.

Specifically, the material for constituting the first layer 52a is preferably selected in a way that the contact resistance (contact resistance) value between the first photoelectric converter 51 and the first layer 52a is smaller than the contact resistance value in a case where the first photoelectric converter 51 is in direct contact with the second layer 52b.

For example, ZnO, ITO, or the like can be used as the first layer 52a.

Note that, in the first embodiment of the present invention, the first layer 52a corresponds to a “contact layer” of the present invention. Moreover, the second layer 52b corresponds to a “low-refractive-index layer” of the present invention.

Meanwhile, the material constituting the first layer 52a is preferably selected in a way that resistance values at both ends of the stacked body 5 including the first layer 52a are smaller than resistance values at both ends of a stacked body 5 not including the first layer 52a.

The backside electrode layer 4 has conductivity. ZnO, silver (Ag), or the like can be used as the backside electrode layer 4, which is not, however, limited to these. The backside electrode layer may have a structure in which a layer containing ZnO and a layer containing Ag are stacked in this order when viewed from the stacked body 5 side. Alternatively, the backside electrode layer 4 may only have a layer containing Ag.

### EFFECTS AND ADVANTAGES

In the solar cell 10 according to the first embodiment of the present invention, the reflective layer 52 includes: the second layer 52b containing the refractive index-modifier; and the first layer 52a formed of the material having the contact resistance value with respect to the first photoelectric converter 51 being smaller than the contact resistance value between the second layer 52b and the first photoelectric converter 51. The first layer 52a and the second layer 52b are stacked in this order when viewed from the first photoelectric converter 51 side.

Accordingly, the second layer 52b is not in direct contact with the first photoelectric converter 51, and thereby the solar cell 10 achieves the improvement in its photoelectric conversion efficiency. This effect will be described in detail below.

In the solar cell 10 according to the first embodiment of the present invention, the second layer 52b included in the reflective layer 52 contains the refractive index-modifier constituted of a material having a lower refractive index than ZnO which has been conventionally used as a main body of a reflective layer. The refractive index of such a second layer 52b as a whole is lower than the refractive index of a layer constituted of ZnO. For this reason, by including such a second layer 52b in the reflective layer 52, it is possible to make the reflectivity of the reflective layer 52 higher than that of a conventional reflective layer mainly formed of ZnO.

Here, when the reflective layer 52 does not include the first layer 52a, or when the first layer 52a and the second layer 52b are stacked in this order when viewed from the backside electrode layer 4 side, the second layer 52b containing the refractive index-modifier comes into direct contact with the first photoelectric converter 51. The contact resistance value between the second layer 52b containing the refractive index-modifier and the first photoelectric converter 51 mainly formed of silicon is a considerably high value. Thus, when the second layer 52b comes into direct contact with the first photoelectric converter 51, the series resistance (series resistance) value of the solar cell 10 as a whole increases. Accordingly, the short-circuit current generated in the solar cell 10 increases in accordance with the increase in the reflectivity of the reflective layer 52. Meanwhile, the fill factor (F. F.) of the solar cell 10 decreases in accordance with the increase in the series resistance. Consequently, the solar cell 10 cannot achieve a sufficient improvement in its photoelectric conversion efficiency.

Thus, in the solar cell 10 according to the first embodiment of the present invention, the first layer 52a and the second layer 52b are stacked in this order when viewed from the first photoelectric converter 51 side. Thereby, the second layer 52b containing the refractive index-modifier is prevented from coming into direct contact with the first photoelectric converter 51. Such a structure makes it possible to suppress the decrease in the fill factor (F. F.) of the solar cell 10 due to the increase in the series resistance of the solar cell 10 as a whole, and simultaneously to increase the reflectivity of the reflective layer 52. As a result, the solar cell 10 achieves the improvement in its photoelectric conversion efficiency.

### Second Embodiment

Hereinbelow, a second embodiment of the present invention will be described. Note that, in the following description, a difference between the above-described first embodiment and the second embodiment will be mainly described.

Specifically, in the above-described first embodiment, the stacked body 5 includes the first photoelectric converter 51 and the reflective layer 52. On the other hand, in the second embodiment, a stacked body 5 has a structure including a second photoelectric converter 53 in addition to a first photoelectric converter 51 and a reflective layer 52, i.e., a so-called tandem structure.

<Structure of Solar Cell>

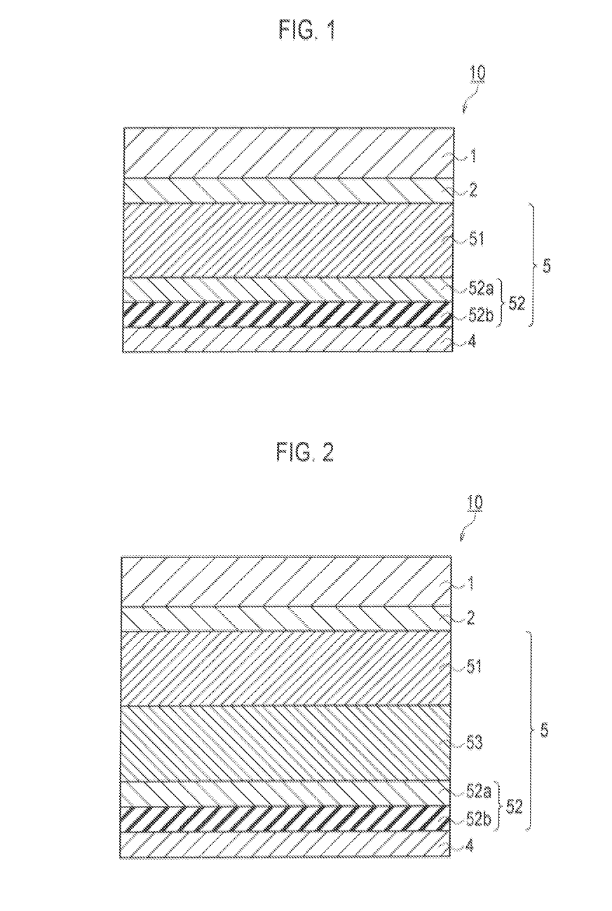

Hereinbelow, a structure of a solar cell according to the second embodiment of the present invention will be described with reference to FIG. 2.

FIG. 2 is a cross-sectional view of the solar cell 10 according to the second embodiment of the present invention.

As shown in FIG. 2, the solar cell 10 includes a substrate 1, a light-receiving-surface electrode layer 2, the stacked body 5, and a backside electrode layer 4.

The stacked body 5 is provided between the light-receiving-surface electrode layer 2 and the backside electrode layer 4. The stacked body 5 includes the first photoelectric converter 51, the reflective layer 52, and the second photoelectric converter 53.

The first photoelectric converter 51, the second photoelectric converter 53, and the reflective layer 52 are stacked in this order when viewed from the light-receiving-surface electrode layer 2 side.

The first photoelectric converter 51 generates photo-generated carriers from light incident from the light-receiving-surface electrode layer 2 side thereof. The first photoelectric converter 51 has a pin junction (unillustrated) in which a p type amorphous silicon semiconductor, an i type amorphous silicon semiconductor, and an n type amorphous silicon semiconductor are stacked in this order when viewed from the substrate 1 side.

The reflective layer 52 reflects a part of light incident from the first photoelectric converter 51 side, toward the first photoelectric converter 51. The reflective layer 52 includes the first layer 52a and the second layer 52b. The first layer 52a and the second layer 52b are stacked in this order when viewed from the first photoelectric converter 51 side. Accordingly, the first layer 52a is in contact with the second photoelectric converter 53, whereas the second layer 52b is not in contact with the second photoelectric converter 53.

The second photoelectric converter 53 generates photo-generated carriers from incident light. The second photoelectric converter 53 has a pin junction (unillustrated) in which a p type crystalline silicon semiconductor, an i type crystalline silicon semiconductor, and an n type crystalline silicon semiconductor are stacked in this order when viewed from the substrate 1 side.

### EFFECTS AND ADVANTAGES

In the solar cell 10 according to the second embodiment of the present invention, the first layer 52a and the second layer 52b included in the reflective layer 52 are stacked in this order when viewed from the first photoelectric converter 51 side.

Even though the solar cell 10 has the tandem structure, such a structure makes it possible to suppress the increase in the series resistance value of the solar cell 10 as a whole, and simultaneously to increase the reflectivity of the reflective layer 52. Thus, the solar cell 10 achieves the improvement in its photoelectric conversion efficiency.

### Third Embodiment

Hereinbelow, a third embodiment of the present invention will be described. Note that, in the following description, a difference between the above-described first embodiment and the third embodiment will be mainly described.

Specifically, in the above-described first embodiment, the stacked body 5 includes the first photoelectric converter 51 and the reflective layer 52. On the other hand, in the third embodiment, a stacked body 5 has a structure including a second photoelectric converter 53 in addition to a first photoelectric converter 51 and a reflective layer 52, i.e., a so-called tandem structure. Furthermore, in the third embodiment, the reflective layer 52 includes a third layer 52c in addition to a first layer 52a and a second layer 52b.

<Structure of Solar Cell>

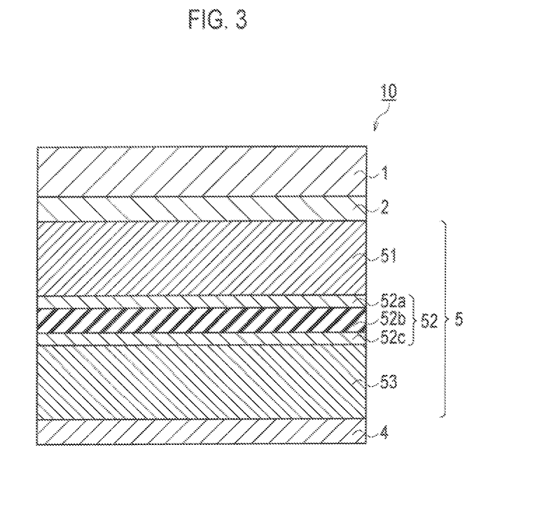

Hereinbelow, a structure of a solar cell according to the third embodiment of the present invention will be described with reference to FIG. 3.

FIG. 3 is a cross-sectional view of the solar cell 10 according to the third embodiment of the present invention.

As shown in FIG. 3, the solar cell 10 includes a substrate 1, a light-receiving-surface electrode layer 2, the stacked body 5, and a backside electrode layer 4.

The stacked body 5 is provided between the light-receiving-surface electrode layer 2 and the backside electrode layer 4. The stacked body 5 includes the first photoelectric converter 51, the reflective layer 52, the second photoelectric converter 53.

The first photoelectric converter 51, the reflective layer 52, and the second photoelectric converter 53 are stacked in this order when viewed from the light-receiving-surface electrode layer 2 side.

The first photoelectric converter 51 generates photo-generated carriers from light incident from the light-receiving-surface electrode layer 2 side thereof. Moreover, the first photoelectric converter 51 generates photo-generated carriers from light reflected by the reflective layer 52. The first photoelectric converter 51 has the pin junction (unillustrated) in which the p type amorphous silicon semiconductor, an i type amorphous silicon semiconductor, and an n type amorphous silicon semiconductor are stacked in this order when viewed from the substrate 1 side.

The reflective layer 52 reflects a part of light, which has transmitted through the first photoelectric converter 51, toward the first photoelectric converter 51. The reflective layer 52 includes the first layer 52a, the second layer 52b, and the third layer 52c.

The first layer 52a, the second layer 52b and the third layer 52c are stacked in this order when viewed from the first photoelectric converter 51 side. Accordingly, the first layer 52a is in contact with the first photoelectric converter 51, and the third layer 52c is in contact with the second photoelectric converter 53. The second layer 52b is in contact with neither the first photoelectric converter 51 nor the second photoelectric converter 53.

The second layer 52b contains: a binder constituted of a resin or the like; a transparent conductive material; and a refractive index-modifier. Silica or the like can be used as the binder. Moreover, ZnO, ITO, or the like can be used as the transparent conductive material. Furthermore, a material having a lower refractive index than a refractive index of the first layer 52a and a refractive index of the third layer 53c is used as the refractive index-modifier. For example, bubbles or fine particles constituted of SiO₂, Al₂O₃, MgO, CaF₂, NaF, CaO, LiF, MgF₂, SrO, B₂O₃, or the like can be used as the refractive index-modifier. Thus, a layer containing, for example, ITO particles and bubbles in a silica based binder can be used as the second layer 52b. Since the second layer 52b contains the refractive index-modifier as described above, the refractive index of the second layer 52b as a whole is lower than the refractive index of the first layer 52a and the refractive index of the third layer 52c.

A material used as a main body of the first layer 52a has a contact resistance value with respect to the first photoelectric converter 51 being smaller than the contact resistance value between the material constituting the second layer 52b and the first photoelectric converter 51. Meanwhile, a material used as a main body of the third layer 53c has a contact resistance value with respect to the second photoelectric converter 53 being smaller than the contact resistance value between the material constituting the second layer 52b and the first photoelectric converter 51.

Specifically, the material constituting the first layer 52a is preferably selected in a way that the contact resistance value between the first photoelectric converter 51 and the first layer 52a is smaller than the contact resistance value in a case where the first photoelectric converter 51 directly comes into contact with the second layer 52b. Meanwhile, the material constituting the third layer 52c is preferably selected in a way that the contact resistance value between the third layer 2c and the second photoelectric converter 53 is smaller than the contact resistance value in a case where the second layer 52b directly comes into contact with the second photoelectric converter 53.

Meanwhile, the material constituting the first layer 52a and the material constituting the third layer 52c are preferably selected in a way that resistance values at both ends of the stacked body 5 including the first layer 52a and the third layer 52c are smaller than resistance values at both ends of stacked body 5 not including the first layer 52a and the third layer 52c.

For example, ZnO, ITO, or the like can be used as the first layer 52a or the third layer 52c. In addition, the material constituting the first layer 52a may be the same as or different from the material constituting the third layer 52c.

Note that, in the third embodiment of the present invention, the third layer 52c corresponds to a “different contact layer” of the present invention.

The second photoelectric converter 53 generates photo-generated carriers from incident light. The second photoelectric converter 53 has a pin junction (unillustrated) in which a p type crystalline silicon semiconductor, an i type crystalline silicon semiconductor, and an n type crystalline silicon semiconductor are stacked in this order when viewed from the substrate 1 side.

### EFFECTS AND ADVANTAGES

In the solar cell 10 according to the third embodiment of the present invention, the reflective layer 52 includes: the second layer 52b containing the refractive index-modifier; the first layer 52a formed of the material having the contact resistance value with respect to the first photoelectric converter 51 being smaller than the contact resistance value between the second layer 52b and the first photoelectric converter 51; and the third layer 52c formed of the material having the contact resistance value with respect to the second photoelectric converter 53 being smaller than the contact resistance value between the second layer 52b and the second photoelectric converter 53. The first layer 52a, the second layer 52b and the third layer 52c are stacked in this order when viewed from the first photoelectric converter 51 side. Accordingly, the second layer 52b containing the refractive index-modifier is in contact with neither the first photoelectric converter 51 nor the second photoelectric converter 53.

Such a structure makes it possible to suppress the increase in the series resistance value of the solar cell 10 as a whole, and simultaneously to increase the reflectivity of the reflective layer 52. This allows the first photoelectric converter 41 to absorb a larger amount of light.

Furthermore, the reflective layer 52 including the second layer 52b containing the refractive index-modifier is less likely to absorb light in a long wavelength region (around 1000 nm) than a conventional reflective layer mainly formed of ZnO does. For this reason, the second photoelectric converter 53 can absorb a larger amount of light. Thus, the solar cell 10 achieves the improvement in its photoelectric conversion efficiency.

### Fourth Embodiment

Hereinbelow, a fourth embodiment of the present invention will be described. Note that, in the following description, a difference between the above-described third embodiment and the fourth embodiment will be mainly described.

Specifically, in the above-described third embodiment, the solar cell 10 includes the substrate 1, the light-receiving-surface electrode layer 2, the stacked body 5, and the backside electrode layer 4. On the other hand, in the fourth embodiment, a solar cell 10 includes multiple solar cell elements 10a on a substrate 1, each of the solar cell elements 10a including a light-receiving-surface electrode layer 2, a stacked body 5 and a backside electrode layer 4.

<Structure of Solar Cell>

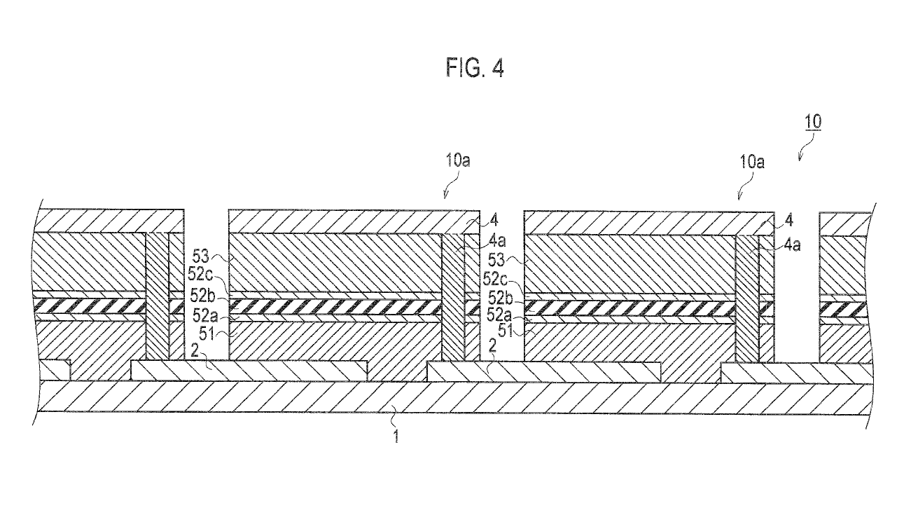

Hereinbelow, a structure of the solar cell according to the fourth embodiment of the present invention will be described with reference to FIG. 4. FIG. 4 is a cross-sectional view of the solar cell 10 according to the fourth embodiment of the present invention.

As shown in FIG. 4, the solar cell 10 includes the substrate 1 and the multiple solar cell elements 10a.

Each of the multiple solar cell elements 10a is formed on the substrate 1. The multiple solar cell elements 10a each include the light-receiving-surface electrode layer 2, the stacked body 5, and the backside electrode layer 4.

The stacked body 5 is provided between the light-receiving-surface electrode layer 2 and the backside electrode layer 4. The stacked body 5 includes a first photoelectric converter 51, a reflective layer 52, and a second photoelectric converter 53. The reflective layer 52 includes a first layer 52a, a second layer 52b, and a third layer 52c.

The first layer 52a, the second layer 52b and the third layer 52c are stacked in this order when viewed from the first photoelectric converter 51 side. Accordingly, the first layer 52a is in contact with the first photoelectric converter 51, and the third layer 52c is in contact with the second photoelectric converter 53. The second layer 52b is in contact with neither the first photoelectric converter 51 nor the second photoelectric converter 53. The first layer 52a and the third layer 52c each preferably have a thickness as small as possible.

The backside electrode layer 4 has an extended portion 4a which extends toward the light-receiving-surface electrode layer 2 of a different solar cell element 10a adjacent to a solar cell element 10a among the multiple solar cell elements 10a.

The extended portion 4a is formed along a side surface of the stacked body 5 included in the one solar cell element 10a. The extended portion 4a is in contact with the reflective layer 52 exposed from the side surface of the stacked body 5 included in the one solar cell element 10a.

### EFFECTS AND ADVANTAGES

The solar cell 10 according to the fourth embodiment of the present invention makes it possible to increase the reflectivity of the reflective layer 52, and to suppress the decrease in the fill factor (FF) of the solar cell 10. Thus, the solar cell 10 achieves the improvement in its photoelectric conversion efficiency. This effect will be described in detail below.

ZnO conventionally used as a main body of a reflective layer has a sheet resistance value of approximately 1.0×10² to 5.0×10²Ω/□. Accordingly, when the conventional reflective layer mainly formed of ZnO is used, some of currents generated in the solar cell element 10a flow to the extended portion 4a along the reflective layer, causing a leak current. When such a leak current is increased in each of the multiple solar cell elements 10a, the fill factor (F. F.) of the solar cell 10 is decreased.

In contrast, the second layer 52b containing the refractive index-modifier has a sheet resistance value of 1.0×10⁶Ω/□ or larger. Thus, in the solar cell 10 according to the fourth embodiment of the present invention, by including the second layer 52b containing the refractive index-modifier in the reflective layer 52, it is possible to significantly make the sheet resistance value of the reflective layer 52 higher than the sheet resistance value of the conventional reflective layer mainly formed of ZnO. For this reason, in the solar cell 10 according to the fourth embodiment of the present invention, the current generated in the solar cell element 10a can be prevented from reaching the extended portion 4a along the reflective layer 52. Accordingly, using the reflective layer 52 including the second layer 52b makes it possible to suppress the decrease in the fill factor (FF) of the solar cell 10 in comparison with a case of using the conventional reflective layer mainly formed of ZnO. As described above, the solar cell 10 achieves the improvement in its photoelectric conversion efficiency.

Moreover, the first layer 52a (contact layer) decreases the contact resistance value between the second layer 52b (low-refractive-index layer) and the first photoelectric converter 51, while the third layer 52c (different contact layer) decreases the contact resistance value between the second layer 52b (low-refractive-index layer) and the second photoelectric converter 53. Accordingly, the thicknesses of the first layer 52a and the third layer 52c can be decreased.

When the thickness of the first layer 52a is decreased, the sheet resistance value of the first layer 52a can be increased. Moreover, when the thickness of the third layer 52c is decreased, the sheet resistance value of the third layer 52c can be increased. In this regard, even when the thickness of the first layer 52a is decreased, the contact resistance value between the second layer 52b (low-refractive-index layer) and the first photoelectric converter 51 can be decreased sufficiently. Moreover, even when the thickness of the first layer 52C is decreased, the contact resistance value between the second layer 32b (low-refractive-index layer) and the first photoelectric converter 31 can be decreased sufficiently. For this reason, by decreasing the thicknesses of the first layer 52a and the third layer 52c as small as possible, a leak current flowing to the extended portion 4a along the first layer 52a and the third layer 52c can be decreased.

### Other Embodiments

The present invention has been described on the basis of the aforementioned embodiments. However, the description and the drawings constituting parts of this disclosure are not construed to limit this invention. Various alternative embodiments, examples, and operation techniques will be apparent to those skilled in the art from this disclosure.

For example, in the above-described first embodiment, the stacked body 5 includes a single photoelectric converter (first photoelectric converter 51). Meanwhile, in the second embodiment and the third embodiment, the stacked body 5 includes two photoelectric converters (first photoelectric converter 51 and second photoelectric converter 53). However, the present invention is not limited to these. Specifically, the stacked body 5 may include three or more photoelectric converters. In such a case, the reflective layer 52 can be provided between any two adjacent photoelectric converters.

Moreover, in the above-described first embodiment, the first photoelectric converter 51 has the pin junction in which the p type amorphous silicon semiconductor, the i type amorphous silicon semiconductor, and the n type amorphous silicon semiconductor are stacked in this order when viewed from the substrate 1 side. However, the structure thereof is not limited to this. Specifically, the first photoelectric converter 51 may have a pin junction in which a p type crystalline silicon semiconductor, an i type crystalline silicon semiconductor, and an n type crystalline silicon semiconductor are stacked in this order when viewed from the substrate 1 side. Note that the crystalline silicon includes microcrystalline silicon and polycrystalline silicon.

Moreover, in the above-described first embodiment to fourth embodiment, the first photoelectric converter 51 and the second photoelectric converter 53 has the pin junction. However, the structure thereof is not limited. Specifically, at least one of the first photoelectric converter 51 and the second photoelectric converter 53 may have a pn junction in which a p type silicon semiconductor and an n type silicon semiconductor are stacked in this order when viewed from the substrate 1 side.

Moreover, in the above-described first embodiment to fourth embodiment, the solar cell 10 has the structure in which the light-receiving-surface electrode layer 2, the stacked body 5, and the backside electrode layer 4 are sequentially stacked on the substrate 1. However, the structure thereof is not limited to this. Specifically, the solar cell 10 may have a structure in which the backside electrode layer 4, the stacked body 5, and the light-receiving-surface electrode layer 2 are sequentially stacked on the substrate 1.

As described above, it is needless to say that the present invention includes various embodiments and the like not described herein. Therefore, the technical scope of the present invention should only be defined by the matter to be claimed according to the scope of claims reasonably understood by the above description.

### EXAMPLES

Hereinafter, a solar cell according to the present invention will be specifically described by way of Examples. However, the present invention is not limited to Examples described below, and thus can be carried out by making appropriate changes without departing from the scope of the gist thereof.

[Refractive Index Evaluation]

First, a comparison was made between the refractive index of a layer containing ITO particles (transparent conductive material) and bubbles (refractive index-modifier) in a silica based binder (hereinafter, the layer is referred to as a bubbles-containing ITO layer), and the refractive indexes of a ZnO layer and an ITO layer which are each conventionally used as a main body of a reflective layer.

Specifically, first, the bubbles-containing ITO layer was formed by a spin coating method, using a dispersion liquid obtained by mixing the ITO fine particles and the silica based binder in an alcohol solvent. In this event, the dispersion liquid was mechanically stirred to thereby contain the bubbles in the dispersion liquid, immediately before the spin coating method was conducted. Note that, ITO fine particles (SUFP), having an average particle diameter of 20 to 40 nm, manufactured by Sumitomo Metal Mining Co., Ltd. was used as the ITO fine particles. Meanwhile, the mixing proportion of the silica based binder was 10 to 15 volume % relative to the ITO fine particles.

Then, after the spin coating, annealing was conducted in air at 150° C. for 1 hour for drying and calcination.

Thereafter, the refractive index of the formed bubbles-containing ITO layer was measured. Table 1 shows the refractive index-measurement result of the bubbles-containing ITO layer.

TABLE 1
Refractive Index of Bubbles-Containing ITO Layer

| | Refractive index |
|---|---|
| Bubbles-containing ITO layer | 1.48 to 1.52 |

Generally, the refractive indexes of a ZnO layer and an ITO layer are approximately 2.0. Accordingly, it was confirmed, as shown in Table 1, that the refractive index of the bubbles-containing ITO layer was lower than the refractive indexes of the ZnO layer and the ITO layer. Thus, by including the bubbles-containing ITO layer in the reflective layer, it is possible to increase the reflectivity of the reflective layer.

[Photoelectric Conversion Efficiency Evaluation]

Next, solar cells according to Example 1, Example 2, Comparative Example 1, Comparative Example 2 and Comparative Example 3 were manufactured as follows, and a comparison was made on the photoelectric conversion efficiency thereamong.

### Example 1

A solar cell 10 according to Example 1 was manufactured as follows. First, a SnO₂ layer (light-receiving-surface electrode layer 2) was formed on a glass substrate (substrate 1) having a thickness of 4 mm.

Then, a p type amorphous silicon semiconductor, an i type amorphous silicon semiconductor, and an n type amorphous silicon semiconductor were stacked on the SnO₂ layer (light-receiving-surface electrode layer 2) by using a plasma CVD method to form a first cell (first photoelectric converter 51). The thicknesses of the p type amorphous silicon semiconductor, the i type amorphous silicon semiconductor, and the n type amorphous silicon semiconductor were respectively 15 nm, 200 nm, and 30 nm.

Then, an intermediate reflective layer (reflective layer 52) was formed on the first cell (first photoelectric converter 51) by using a sputtering method and a spin coating method. Specifically, a ZnO layer (first layer 52a) formed by the sputtering method, a bubbles-containing ITO layer (second layer 52b) formed by the spin coating method and a ZnO layer (third layer 52c) formed by the sputtering method were sequentially stacked on the first cell (first photoelectric converter 51). Thereby, the intermediate reflective layer (reflective layer 52) having a three-layered structure was formed. The thicknesses of the ZnO layer (first layer 52a), the bubbles-containing ITO layer (second layer 52b), and the ZnO layer (third layer 52c) were respectively 5 nm, 20 nm, and 5 nm.

Then, a p type microcrystalline silicon semiconductor, an i type microcrystalline silicon semiconductor, and an n type microcrystalline silicon semiconductor were stacked on the intermediate reflective layer (reflective layer 52) by using a plasma CVD method. Thereby, a second cell (second photoelectric converter 53) was formed. The thicknesses of the p type microcrystalline silicon semiconductor, the i type microcrystalline silicon semiconductor, and the n type microcrystalline silicon semiconductor were respectively 30 nm, 2000 nm, and 20 nm.

Then, a ZnO layer and an Ag layer (backside electrode layer 4) were formed on the second cell (second photoelectric converter 53) by using a sputtering method. The thicknesses of the ZnO layer and the Ag layer (backside electrode layer 4) were respectively 90 nm and 200 nm.

As described above, in this Example 1, the solar cell 10 was formed as shown in FIG. 3, the solar cell 10 having the intermediate reflective layer (reflective layer 52) including the bubbles-containing ITO layer (second layer 52b) between the first cell (first photoelectric converter 51) and the second cell (second photoelectric converter 53). Moreover, the ZnO layer (first layer 52a) was interposed between the bubbles-containing ITO layer (second layer 52b) and the first cell (first photoelectric converter 51), and the ZnO layer (third layer 52c) was interposed between the bubbles-containing ITO layer (second layer 52b) and the second cell (second photoelectric converter 53).

### Comparative Example 1

A solar cell 20 according to Comparative Example 1 was manufactured as follows. First, as similar to Example 1 described above, a SnO₂ layer (light-receiving-surface electrode layer 22) and a first cell (first photoelectric converter 251) were sequentially formed on a glass substrate (substrate 21) having a thickness of 4 mm.

Then, an intermediate reflective layer (reflective layer 252) was formed on the first cell (first photoelectric converter 251) by using a sputtering method. In this Comparative Example 1, only a ZnO layer was formed on the first cell (first photoelectric converter 251), and this ZnO layer served as the intermediate reflective layer (reflective layer 252). The thickness of the ZnO layer (reflective layer 252) was 30 nm.

Then, as similar to Example 1 described above, a second cell (second photoelectric converter 253), a ZnO layer and an Ag layer (backside electrode layer 24) were sequentially formed on the intermediate reflective layer (reflective layer 252). Note that the thicknesses of the first cell (first photoelectric converter 251), the second cell (second photoelectric converter 253), the ZnO layer and the Ag layer (backside electrode layer 24) were the same as those in Example 1 described above.

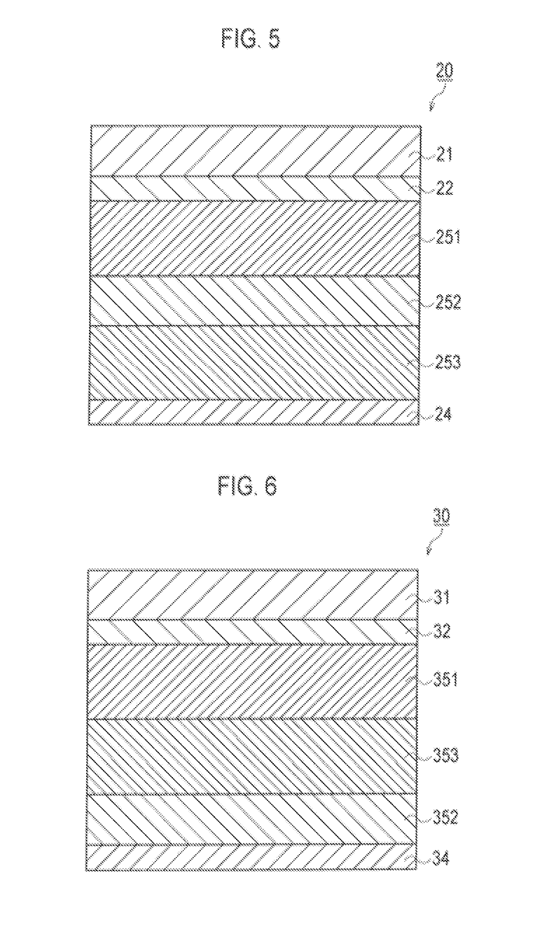

As described above, in this Comparative Example 1, the solar cell 20 was formed as shown in FIG. 5, the solar cell 20 having the intermediate reflective layer (reflective layer 252) constituted of the ZnO layer between the first cell (first photoelectric converter 251) and the second cell (second photoelectric converter 253).

### Comparative Example 2

A solar cell 20 according to Comparative Example 2 was manufactured as follows. First, as similar to Example 1 described above, a SnO₂ layer (light-receiving-surface electrode layer 22) and a first cell (first photoelectric converter 251) were sequentially formed on a glass substrate (substrate 21) having a thickness of 4 mm.

Then, an intermediate reflective layer (reflective layer 252) was formed on the first cell (first photoelectric converter 251) by using a sputtering method. In this Comparative Example 2, only a bubbles-containing ITO layer was formed on the first cell (first photoelectric converter 251), and this bubbles-containing ITO layer served as the intermediate reflective layer (reflective layer 252). The thickness of the bubbles-containing ITO layer (reflective layer 252) was 30 nm.

Then, as similar to Example 1 described above, a second cell (second photoelectric converter 253), a ZnO layer and an Ag layer (backside electrode layer 24) were sequentially formed on the intermediate reflective layer (reflective layer 252). Note that the thicknesses of the first cell (first photoelectric converter 251), the second cell (second photoelectric converter 253), the ZnO layer and the Ag layer (backside electrode layer 24) were the same as those in Example 1 described above.

As described above, in this Comparative Example 2, the solar cell 20 was formed as shown in FIG. 5, the solar cell 30 having the intermediate reflective layer (reflective layer 252) constituted of the bubbles-containing ITO layer between the first cell (first photoelectric converter 251) and the second cell (second photoelectric converter 253).

<Property Evaluation (Part 1)>

A comparison was made on each of property values among the solar cells according to Example 1, Comparative Example 1 and Comparative Example 2. The compared properties were: open-circuit voltage, short-circuit current, fill factor and photoelectric conversion efficiency. Table 2 shows the comparison result. Note that, in Table 2, each property value is normalized with those in Comparative Example 1 taken as 1.00.

TABLE 2
Each property value of solar cells according to Example
1, Comparative Example 1 and Comparative Example 2

| | | | | Photoelectric |
|---|---|---|---|---|
| | Open-circuit | Short-circuit | Fill | conversion |
| | voltage | current | factor | efficiency |
| Comparative | 1.00 | 1.00 | 1.00 | 1.00 |
| Example 1 | | | | |
| Comparative | 0.98 | 1.01 | 0.92 | 0.91 |
| Example 2 | | | | |
| Example 1 | 1.00 | 1.04 | 0.99 | 1.03 |

As shown in Table 2, it was observed that Comparative Example 2 showed a slightly higher short-circuit current than Comparative Example 1, while showing a lower fill factor than Comparative Example 1. As a result, it was observed that Comparative Example 2 had lower photoelectric conversion efficiency than Comparative Example 1.

The higher short-circuit current of the solar cell 20 according to Comparative Example 2 is presumably attributed to the fact that the intermediate reflective layer (reflective layer 252) was constituted of the bubbles-containing ITO layer with a lower refractive index than the ZnO layer. Meanwhile, the lower fill factor of the solar cell 20 according to Comparative Example 2 is presumably attributed to the fact that the direct contact of the bubbles-containing ITO layer constituting the intermediate reflective layer (reflective layer 252) with the first cell (first photoelectric converter 251) and with the second cell (second photoelectric converter 253) increased the series resistance value of the solar cell 20 according to Comparative Example 2. Presumably, having a fill factor lowered to a large extent, Comparative Example 2 achieved the lower photoelectric conversion efficiency than Comparative Example 1.

On the other hand, it was observed that Example 1 showed a slightly lower fill factor than Comparative Example 1, while showing a higher short-circuit current than Comparative Example 1. As a result, it was confirmed that the photoelectric conversion efficiency is improvable in Example 1 in comparison with Comparative Example 1.

### Example 2

A solar cell 10 according to Example 2 was manufactured as follows. First, a SnO₂ layer (light-receiving-surface electrode layer 2) was formed on a glass substrate (substrate 1) having a thickness of 4 mm.

Then, a p type amorphous silicon semiconductor, an i type amorphous silicon semiconductor, and an n type amorphous silicon semiconductor were stacked on the SnO₂ layer (light-receiving-surface electrode layer 2) by using a plasma CVD method to form a first cell (first photoelectric converter 51). The thicknesses of the p type amorphous silicon semiconductor, the i type amorphous silicon semiconductor, and the n type amorphous silicon semiconductor were respectively 15 nm, 360 nm, and 30 nm.

Then, a p type microcrystalline silicon semiconductor, an i type microcrystalline silicon semiconductor, and an n type microcrystalline silicon semiconductor were stacked on the first cell (first photoelectric converter 51) by using a plasma CVD method. Thereby, a second cell (second photoelectric converter 53) was formed. The thicknesses of the p type microcrystalline silicon semiconductor, the i type microcrystalline silicon semiconductor, and the n type microcrystalline silicon semiconductor were respectively 30 nm, 2000 nm, and 20 nm.

Then, an intermediate reflective layer (reflective layer 52) was formed on the second cell (second photoelectric converter 53) by using a sputtering method and a spin coating method. Specifically, an ITO layer (first layer 52a) formed by the sputtering method and a bubbles-containing ITO layer (second layer 52b) formed by the spin coating method were sequentially stacked on the second cell (second photoelectric converter 53). Thereby, the backside reflective layer (reflective layer 52) having a two-layered structure was formed. The thickness each of the ITO layer (first layer 52a) and the bubbles-containing ITO layer (second layer 52b) was 45 nm.

Then, an Ag layer (backside electrode layer 4) was formed on the backside reflective layer (reflective layer 52) by using a sputtering method. The thickness of the Ag layer (backside electrode layer 4) was 200 nm.

As described above, in this Example 2, the solar cell 10 was formed as shown in FIG. 2, the solar cell 10 having the backside reflective layer (reflective layer 52) including the bubbles-containing ITO layer (second layer 52b) between the second cell (second photoelectric converter 53) and the Ag layer (backside electrode layer 4). Moreover, the ITO layer (first layer 52a) was interposed between the bubbles-containing ITO layer (second layer 52b) and the second cell (second photoelectric converter 53).

### Comparative Example 3

A solar cell 30 according to Comparative Example 3 was manufactured as follows. First, as similar to Example 2 described above, a SnO₂ layer (light-receiving-surface electrode layer 52), a first cell (first photoelectric converter 351), and a second cell (second photoelectric converter 353) were sequentially formed on a glass substrate (substrate 31) having a thickness of 4 mm.

Then, a backside reflective layer (reflective layer 352) was formed on the second cell (second photoelectric converter 353) by using a sputtering method. In this Comparative Example 3, only a ZnO layer was formed on the second cell (second photoelectric converter 353), and this ZnO layer served as the backside reflective layer (reflective layer 352). The thickness of the ZnO layer (reflective layer 352) was 90 nm.

Then, as similar to Example 1 described above, an Ag layer (backside electrode layer 34) was formed on the backside reflective layer (reflective layer 352). Note that the thicknesses of the first cell (first photoelectric converter 351), the second cell (second photoelectric converter 353), and the Ag layer (backside electrode layer 34) were the same as those in Example 2 described above.

As described above, in this Comparative Example 3, the solar cell 10 was formed as shown in FIG. 6, the solar cell 30 having the backside reflective layer (reflective layer 352) constituted of the ZnO layer between the second cell (second photoelectric converter 353) and the Ag layer (backside electrode layer 34).

<Property Evaluation (Part 2)>

A comparison was made on each of property values between the solar cells according to Example 2 and Comparative Example 3. The compared properties were: open-circuit voltage, short-circuit current, fill factor and photoelectric conversion efficiency. Table 3 shows the comparison result. Note that, in Table 3, each property value is normalized with those in Comparative Example 3 taken as 1.00.

TABLE 3
Each property value of solar cells according
to Example 2 and Comparative Example 3

| | | | | Photoelectric |
|---|---|---|---|---|
| | Open-circuit | Short-circuit | Fill | conversion |
| | voltage | current | factor | efficiency |
| Comparative | 1.00 | 1.00 | 1.00 | 1.00 |
| Example 3 | | | | |
| Example 2 | 1.00 | 1.06 | 0.99 | 1.05 |

As shown in Table 3, it was observed that Example 2 showed a slightly lower fill factor than Comparative Example 1, while showing a higher short-circuit current was higher than Comparative Example 3. As a result, it was confirmed the photoelectric conversion efficiency is improvable in Example 2 in comparison with Comparative Example 3.

### INDUSTRIAL APPLICABILITY

According to the present invention, it is possible to provide a solar cell having an improved photoelectric conversion efficiency. The present invention is therefore useful in the field of solar power generation.

1. A solar cell comprising:
a light-receiving-surface electrode layer having conductivity and transparency;
a backside electrode layer having conductivity; and
a stacked body provided between the light-receiving-surface electrode layer and the backside electrode layer, wherein
the stacked body includes:
a first photoelectric converter generating photo-generated carriers from incident light; and
a reflective layer reflecting a part of light, which has transmitted through the first photoelectric converter, toward the first photoelectric converter,
the reflective layer includes:
a low-refractive-index layer containing a refractive index-modifier; and
a contact layer interposed between the low-refractive-index layer and the first photoelectric converter,
a refractive index of a material constituting the refractive index-modifier is lower than a refractive index of a material constituting the contact layer, and
a refractive index of the low-refractive-index layer is lower than a refractive index of the contact layer.

2. The solar cell according to claim 1, wherein
the stacked body has a structure in which the first photoelectric converter, the reflective layer, and a second photoelectric converter for generating photo-generated carriers from incident light are stacked in this order when viewed from a light-receiving-surface electrode layer side,
the reflective layer further includes a different contact layer interposed between the low-refractive-index layer and the second photoelectric converter,
the refractive index of the material constituting the refractive index-modifier is lower than a refractive index of a material constituting the different contact layer, and
the refractive index of the low-refractive-index layer is lower than a refractive index of the different contact layer.

3. The solar cell according to any one of claims 1 and 2, wherein the contact layer is constituted of a material having a smaller contact resistance value with respect to the first photoelectric converter than a contact resistance value between the low-refractive-index layer and the first photoelectric converter.

4. The solar cell according to claim 2, wherein
the different contact layer is constituted of a material having a smaller contact resistance value with respect to the second photoelectric converter than a contact resistance value between the low-refractive-index layer and the second photoelectric converter.

5. The solar cell according to any one of claims 3 and 4, wherein
at least one of the contact layer and the different contact layer contains any one of zinc oxide and indium oxide.

6. A solar cell comprising a first solar cell element and a second solar cell element on a substrate having an insulating property and transparency, wherein
each of the first solar cell element and the second solar cell element includes:
a light-receiving-surface electrode layer having conductivity and transparency;
a backside electrode layer having conductivity; and
a stacked body provided between the light-receiving-surface electrode layer and the backside electrode layer,
the stacked body has:
a first photoelectric converter generating photo-generated carriers from incident light;
a reflective layer reflecting a part of light, which has transmitted through the first photoelectric converter, toward the first photoelectric converter; and
a second photoelectric converter generating photo-generated carriers from incident light,
the backside electrode layer of the first solar cell element has an extended portion extending toward the light-receiving-surface electrode layer of the second solar cell element,
the extended portion is in contact with the reflective layer exposed from a side surface of the stacked body included in the first solar cell element,
the reflective layer has: a low-refractive-index layer containing a refractive index-modifier; a contact layer interposed between the low-refractive-index layer and the first photoelectric converter; and a different contact layer interposed between the low-refractive-index layer and the second photoelectric converter,
a refractive index of a material constituting the refractive index-modifier is lower than a refractive index of a material constituting the contact layer and a refractive index of a material constituting the different contact layer, and
a refractive index of the low-refractive-index layer is lower than a refractive index of the contact layer and a refractive index of the different contact layer.
